(19) United States
(12) Patent Application Publication
(10) Pub. No.: US 2023/0281355 A1
(43) Pub. Date: Sep. 7, 2023

(54) Method For Selection Of Cement Composition For Wells Experiencing Cyclic Loads

(71) Applicant: Halliburton Energy Services, Inc., Houston, TX (US)

(72) Inventors: Siva Rama Krishna Jandhyala, Houston, TX (US); Walmy Cuello Jimenez, Houston, TX (US)

(73) Assignee: Halliburton Energy Services, Inc., Houston, TX (US)

(21) Appl. No.: 17/701,921

(22) Filed: Mar. 23, 2022

Related U.S. Application Data
(60) Provisional application No. 63/316,725, filed on Mar. 4, 2022.

(51) Int. Cl. G06F 30/20; C09K 8/46; E21B 33/14; G06Q 10/06; G06Q 50/08

(52) U.S. Cl. CPC G06F 30/20; C09K 8/46; E21B 33/14; G06Q 10/06313; G06Q 50/08; E21B 2200/20

(57) ABSTRACT

Methods of the present disclosure relate to quantitative assessments of the risk of damage to cement sheaths due to cyclic loads. A method comprises selecting cement compositions; performing wellbore integrity analyses using models for cement sheaths, each cement sheath comprising a selected cement composition; and determining a number of cycles to failure for each cement sheath.

### BACKGROUND

Technological advances in well construction and completion have enabled economic recovery of trapped hydrocarbon. Examples of these technologies are multi-stage hydraulic fracturing, water alternating gas (WAG), and steam assisted gravity drainage (SAGD). These technologies exert repeated structural and/or thermal loads on wellbore materials, specifically casing and the cement sheath. The response of steel to cyclic loading has been studied and established casing design techniques exist to model the effect of cyclic loads. However, these techniques do not analyze, tailor, and select cement systems for wells experiencing cyclic loads.

### BRIEF DESCRIPTION OF THE DRAWINGS

These drawings illustrate certain aspects of some of the examples of the present disclosure and should not be used to limit or define the disclosure.

FIG. 1 illustrates a workflow for designing a cement composition for wells experiencing cyclic loading, in accordance with examples of the present disclosure;

FIG. 2 illustrates a system for the preparation of a designed fluid(s) and subsequent delivery of the fluid to an application site, in accordance with examples of the present disclosure;

FIG. 3 illustrates a system that may be used in the placement of a cement composition, in accordance with examples of the present disclosure;

FIG. 4 illustrates the cement composition placed into a subterranean formation, in accordance with particular examples of the present disclosure; and

FIG. 5 illustrates a wellbore model, in accordance with examples of the present disclosure.

### DETAILED DESCRIPTION

Methods of the present disclosure generally relate to using a near-wellbore integrity (NWBI) design approach, with fatigue material models of cement to analyze suitability of a cement composition for use in wells that may experience cyclic loads. The NWBI approach provides the necessary inputs to the fatigue material model and the fatigue material model in turn predicts the likelihood of cement sheath withstanding cyclic loads. The methods can be used with different types of fatigue material models. Further, the methods are applicable for a range of cyclic load curve shapes, frequencies, and stress levels. Cyclic load can be exerted by variations in temperature and/or pressure in the wellbore.

Existing technologies cannot model effect of fatigue on cement sheath response when analyzing near wellbore integrity. Current design approaches do not consider fatigue loading and its effect on wellbore integrity to tailor cement systems to withstand cyclic stresses.

The methods provide a quantitative assessment of the risk of damage to cement sheath due to cyclic loads, thus reducing unwanted environmental impacts or need for costly remedial operations. Understating the quantitative effect of fatigue loading in oil cement integrity aids in tailoring slurry designs to withstand such conditions and even develop novel cement compositions to better withstand subterranean pressures, temperatures, and/or cyclic stresses.

This results in operators designing fit-for-purpose cement compositions with a maximized objective because actual expected loading cycles are evaluated, and actual expected life may be accurately predicted. Example objectives can be a performance to carbon footprint ratio.

In a first stage, profiles of temperature and pressure vs. time can be inputted into NWBI analysis. In this phase, finite element analysis to evaluate risk of mechanical failure (e.g., cracking) of set cement sheath due to temperature and pressure loads experienced by the well over its life, is performed without any changes to material properties of cement sheath. The objective of this phase is to determine the maximum stress level the cement sheath may experience during cyclic load.

Stress levels can be expressed as a fraction of average compressive strength of cement, average tensile strength of cement or average strength of interfacial bond between cement and other materials. The type of strength to use depends on the dominant nature of failure expected (compressive, tensile, interfacial debonding, etc.) The first phase accounts for critical variables in cyclic loading: shape of the load curve (e.g., sinusoidal, triangular), rate of loading in each cycle, lower and upper level of stress and/or temperature loading in each cycle.

All of these variables may play a role in determining the maximum stress level experienced by the cement sheath. Depending on whether temperature load counteracts or magnifies pressure load, it is possible that the maximum deviatoric stress level, maximum tensile stress or maximum interfacial stress does not correspond to peak values of temperature and pressure. The maximum stress level itself is a function of geometry of the wellbore and the properties of the wellbore materials (e.g., cement sheath, casing, rock), and these are accounted in the analysis performed in the first phase.

In the second stage, the maximum (and minimum if needed) stress level is passed as input(s) to fatigue material model. The output is the number of cycles cement sheath can withstand at that maximum stress level. Fatigue model parameters of the cement composition being used in this step should be known. It is a conservative and prudent design approach to use the maximum stress level from the first stage in a fatigue material model when trying to determine the number of cycles cement sheath can withstand. By repeating this process for different cement systems, it is possible to select a few suitable cement compositions that can withstand the desired number of cycles with a desired probability, if applicable. From the selected few cement compositions, one composition of interest can be selected based on a defined objective that one wants to minimize or maximize. An example of an objective is a performance to carbon footprint ratio. Yet another example of an objective is a performance to cost of materials ratio.

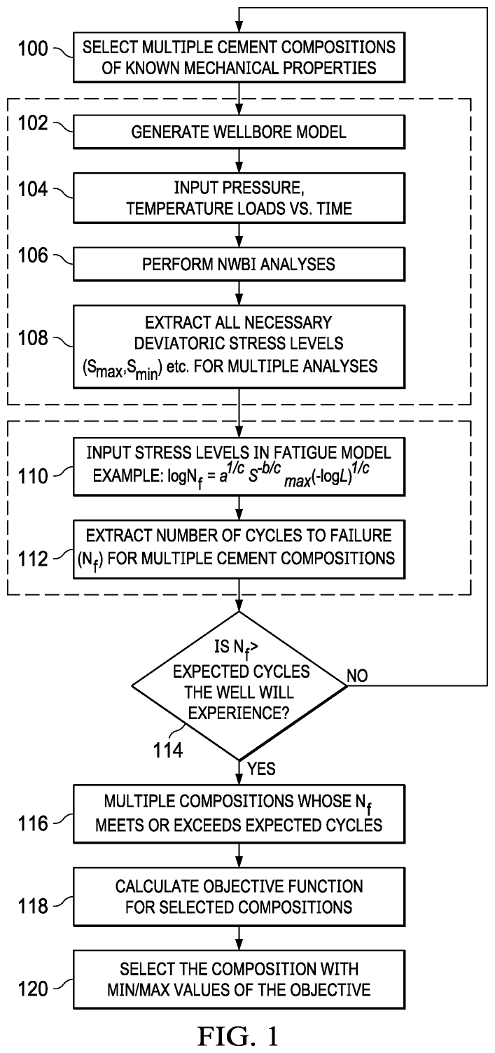

FIG. 1 illustrates a method for designing a cement composition, in accordance with examples of the present disclosure. The method is a near-wellbore integrity (NWBI) design method, that uses fatigue material models of cement, to analyze suitability of a cement composition for use in wells that may experience cyclic loads.

At box 100, multiple cement compositions of known mechanical properties may be selected. Each of the selected cement compositions may be assessed according to the following workflow, and based on results of the workflow, at least one cement composition out of all of the analyzed cement compositions may be chosen for cementing the well. The cement compositions in box 100 may be analyzed sequentially or simultaneously. The known mechanical properties for the cement compositions may include: Young's modulus, Poisson's ratio, tensile strength, compressive strength in confined and unconfined state, shrinkage/expansion, thermal expansion coefficient, thermal conductivity, and volumetric specific heat.

At box 102, a wellbore model may be generated for each cement composition in box 100. Types of models include a 2D plane strain model that is generated using finite element software. When model dimensions (e.g., bore hole size, casing size), loads (e.g., rock pore pressure, drilling temperatures, pressure test values) and material properties (e.g., Young's modulus, Poisson's ratio, thermal expansion etc. of rock, cement and casing) are provided, the finite element software creates geometry, meshes, and assigns loads, material properties, and boundary conditions.

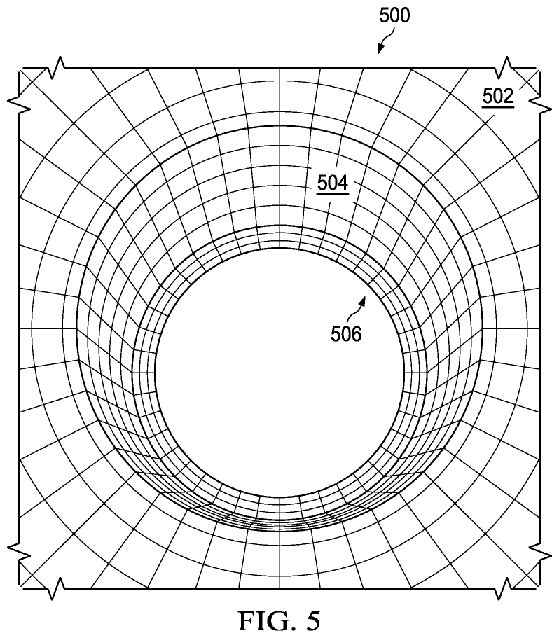

The wellbore model as shown on FIG. 5 for example, is generated using a finite element solver. Each component of the model such as rock, cement, and casing, are discretized in the form of a mesh and the constitutive stress-strain relation is solved at every node on the mesh simultaneously.

At box 104, pressure and temperature loads versus time may be inputted into each wellbore model. An NWBI analysis may be performed at box 106 on each cement composition. The NWBI analysis involves simulating a numerical model of the wellbore construction and operation processes in a thermo-structural finite element framework. Rock, cement sheath and casing dimensions are used to create a mesh model that represents a 2D cross section of wellbore at desired depth. Material models of each of the components is fed to the mesh. Temperature and pressure loads are exerted on different well components at different stages of well life, such as for example, construction, pressure test, and production. Output of the analysis are stresses, strains and deformations of all well components. All of this is performed by considering rock of a finite radius. The assumption is that any changes in pressure or temperature inside the wellbore propagate only a certain radial distance into the rock (i.e., near-wellbore analysis). Deviatoric stress levels (e.g., maximum stress, minimum stress), maximum and minimum tensile stress level and maximum and minimum interfacial stress level for each cement composition may be determined/extracted at box 108. If the fatigue model is based on a strain level instead of a stress level, the strain rates for each cement composition may be determined/extracted at box 108. Boxes 102 to 108 may be performed as a first stage of the workflow.

A second stage may begin at box 110, where the stress levels from box 108 for each cement composition may be inputted into a fatigue model such as for example:

log N_{f}=a^{1/c}S^{-b/c}ₘₐₓ(−log L)^{1/c} (1)

where a, b, c are model parameters; L is survivability (0-1); Sₘₐₓ is maximum stress level, expressed as a fraction of average compressive strength and extracted from box 108;
Yet another example fatigue model is

$$\frac{Δ f}{{f}_{c}^{′}} = 1 - β ( 1 - \frac{{S}_{min}}{{S}_{max}} ) log {N}_{f} \qquad ( 2 )$$

N_{f} is the number of cycles to failure;
where β is model parameter; Sₘᵢₙ, Sₘₐₓ are minimum and maximum stress levels, expressed as a fraction of average compressive strength and extracted from box 108;

$$\frac{Δ f}{{f}_{c}^{′}}$$

is ratio of applied stress to average compressive strength. A third example of a fatigue model is

N_{f}=Aε_{sec}^{B} (3)

N_{f} is the number of cycles to failure;
where A, B are model parameters; ε_{sec} is secondary strain rate; N_{f} is the number of cycles to failure. For a model based on strain rate, strain rate output from box 108 can be used. The number of cycles to failure (N_{f}) for each cement composition is extracted at box 112. The second stage may include boxes 110 and 112. If a tensile nature of failure is expected, models like Equations 1-3 can be used to relate number of cycles to failure with tensile stress level or tensile strains. Similarly, models that relate number of cycles to failure with interface stress level can be used to determine risk of interface bond failure.

At box 114, for each cement composition, a determination may be made as to whether N_{f} is greater than a value such as the expected number of cycles the well will experience. Expected number of cycles may vary, but in some examples, the expected number of cycles may include a number of hydraulic frac stages in a job.

If the condition in box 114 is not satisfied, then the cement composition may be modified until the condition in box 114 is satisfied. That is, stages 1 and 2 may be repeated for a modified cement composition. It should also be noted that stages 1 and 2 are performed for each cement composition in box 100. All of the cement compositions that satisfy box 114 may be deemed suitable at box 116. That is, all of the cement compositions whose N_{f} meets or exceeds expected cycles may be identified and/or stored (e.g., short list) in a database.

At box 118, an objective function for the selected cement compositions may be calculated. Objective functions may include a CO₂ footprint, cost of goods sold (COGS), and/or material usage. At box 120, the cement composition(s) with a min or max value for the objective may be chosen for production.

For example, a determination of the carbon dioxide footprint of each of the cement compositions in block 116, may occur via a model for a carbon footprint (CFP). A goal may be to select the cement composition with the lowest CO₂ footprint from the multiple cement compositions in box 116. The cement composition with the lowest carbon footprint may be selected and produced. The carbon footprint can be quantified in terms of greenhouse gas (CO₂) emission per unit quantity of material. Example values of emissions for different materials are shown in Table 1:

TABLE 1
Example values of emissions for different materials.

| Material | Product GHG [CO₂ Kg/tonne] |
|---|---|
| Portland | 950 |
| Fly Ash | 8 |
| Silicalite | 14 |
| Geo Polymer | 30 |
| CKD | 0 |
| Crystalline Silica | 5.1 |
| Gypsum | 130 |
| CaCO₃ | 32 |
| Lime | 780 |

For unit mass of powder in slurry (m_{powder}=1 gm), the amount of water is defined by:

$${m}_{w a t e r} = \frac{\frac{{ρ}_{slurry}}{{ρ}_{powder}} - 1}{1 - \frac{{ρ}_{slurry}}{{ρ}_{water}}} gms \qquad ( 4 )$$

The volume of slurry per unit mass of powder is:

$${V}_{slurry} = \frac{{m}_{powder}}{{ρ}_{powder}} + \frac{{m}_{water}}{{ρ}_{water}} CC \qquad ( 5 )$$

Carbon footprint is:

$$CFP = \frac{{\sum }_{i} {x}_{i} \times CO {2}_{i}}{{V}_{slurry}} g m / CC \qquad ( 6 )$$

where xᵢ is mass fraction of material i in powder; CO2ᵢ is the emission due to material i in gm/gm.

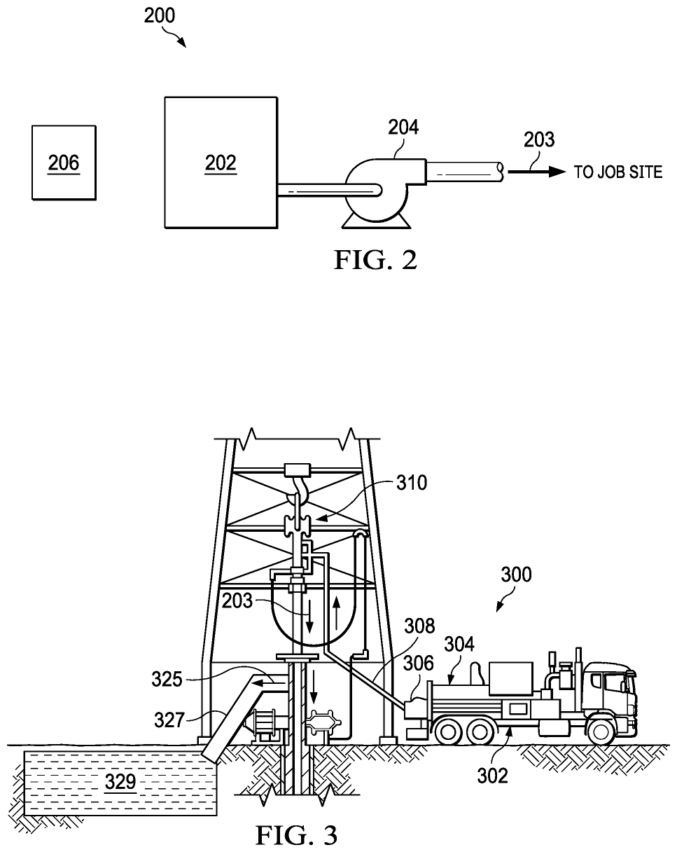

FIG. 2 illustrates a system 200 for the preparation of a designed fluid(s) and subsequent delivery of the fluid to an application site, in accordance with examples of the present disclosure. As shown, components may be mixed and/or stored in a vessel 202. The vessel 202 may be configured to contain and/or mix the components to produce or modify a designed composition 203 (e.g., a fluid, a cement). Non-limiting examples of the vessel 202 may include drums, barrels, tubs, bins, jet mixers, re-circulating mixers, and/or batch mixers. The designed composition 203 may then be moved (e.g., pumped via pumping equipment 204) to a location.

The system 200 may also include a computer 206 for performing the workflow of FIG. 1 and to prepare the designed composition. The computer 206 may include any instrumentality or aggregate of instrumentalities operable to compute, estimate, classify, process, transmit, receive, retrieve, originate, switch, store, display, manifest, detect, record, reproduce, handle, or utilize any form of information, intelligence, or data for business, scientific, control, or other purposes. The computer 206 may be any processor-driven device, such as, but not limited to, a personal computer, laptop computer, smartphone, tablet, handheld computer, dedicated processing device, and/or an array of computing devices. In addition to having a processor, the computer 206 may include a server, a memory, input/output (“I/O”) interface(s), and a network interface. The memory may be any computer-readable medium, coupled to the processor, such as RAM, ROM, and/or a removable storage device for storing data and a database management system (“DBMS”) to facilitate management of data stored in memory and/or stored in separate databases.

The computer 206 may also include display devices such as a monitor featuring an operating system, media browser, and the ability to run one or more software applications. Additionally, the computer 206 may include non-transitory computer-readable media. Non-transitory computer-readable media may include any instrumentality or aggregation of instrumentalities that may retain data and/or instructions for a period of time.

FIG. 3 illustrates a system 300 that may be used in the placement of a designed composition, in accordance with examples of the present disclosure. It should be noted that while FIG. 3 generally depicts a land-based operation, those skilled in the art will readily recognize that the principles described herein are equally applicable to subsea operations that employ floating or sea-based platforms and rigs, without departing from the scope of the disclosure.

The system 300 may include a cementing unit 302, which may include one or more cement trucks, for example. The cementing unit 302 may include mixing equipment 304 and pumping equipment 306. The cementing unit 302 may pump the designed composition 203, through a feed pipe 308 and to a cementing head 310 which conveys the composition 203 into a downhole environment.

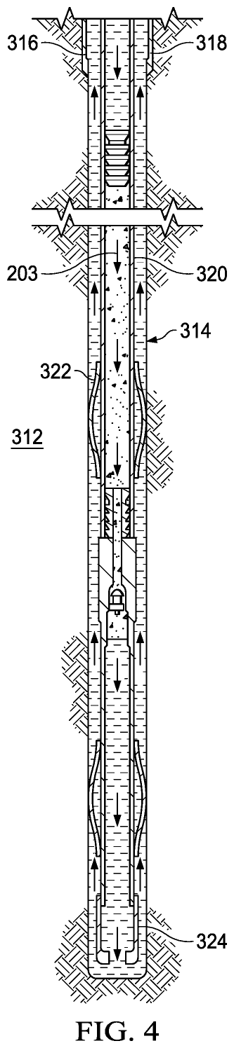

With additional reference to FIG. 4, the composition 203 may be placed in a subterranean formation 312. A wellbore 314 may be drilled into the subterranean formation 312. While the wellbore 314 is shown generally extending vertically into the subterranean formation 312, the principles described herein are also applicable to wellbores that extend at an angle through subterranean formation 312, such as horizontal and slanted wellbores.

A first section 316 of casing may be inserted into the wellbore 314. The section 316 may be cemented in place by a cement sheath 318. A second section 320 of casing may also be disposed in the wellbore 314. A wellbore annulus 322 formed between the second section 320 and walls of the wellbore 314 and/or the first section 316.

The composition 203 may be pumped down the interior of the second section 320 of casing. The composition 203 may be allowed to flow down the interior of the casing through the casing shoe 324 at the bottom of the second section 320 and up around the second section 320 of casing into the wellbore annulus 322. As it is introduced, the composition 203 may displace other fluids 325, such as drilling fluids and/or spacer fluids that may be present in the interior of the casing and/or the wellbore annulus 322. At least a portion of the displaced fluids 325 may exit the wellbore annulus 322 via a flow line 327 and be deposited, for example, in one or more retention pits 329.

FIG. 5 illustrates a wellbore model, in accordance with examples of the present disclosure. The wellbore model 500 is generated using a finite element solver (e.g., the computer 206). Each component of the model such as rock 502, cement 504, and casing 506, are discretized in the form of a mesh and the constitutive stress-strain relation is solved at every node on the mesh simultaneously.

Other techniques may also be utilized for introduction of the composition 203. For example, reverse circulation techniques may be used that include introducing the composition 203 into the subterranean formation 312 via the wellbore annulus 322 instead of through the casing (e.g., section 320).

Cement slurries described herein may generally include a hydraulic cement and water. A variety of hydraulic cements may be utilized in accordance with the present disclosure, including, but not limited to, those comprising calcium, aluminum, silicon, oxygen, iron, and/or sulfur, which set and harden by reaction with water. Suitable hydraulic cements may include, but are not limited to, Portland cements, pozzolana cements, gypsum cements, high alumina content cements, silica cements, and any combination thereof. In certain examples, the hydraulic cement may include a Portland cement. In some examples, the Portland cements may include Portland cements that are classified as Classes A, C, H, and G cements according to American Petroleum Institute, API Specification for Materials and Testing for Well Cements, API Specification 10, Fifth Ed., Jul. 1, 1990. In addition, hydraulic cements may include cements classified by American Society for Testing and Materials (ASTM) in C150 (Standard Specification for Portland Cement), C595 (Standard Specification for Blended Hydraulic Cement) or C1157 (Performance Specification for Hydraulic Cements) such as those cements classified as ASTM Type I, II, or III. The hydraulic cement may be included in the cement slurry in any amount suitable for a particular composition. Without limitation, the hydraulic cement may be included in the cement slurries in an amount in the range of from about 10% to about 80% by weight of dry blend in the cement slurry. For example, the hydraulic cement may be present in an amount ranging between any of and/or including any of about 10%, about 15%, about 20%, about 25%, about 30%, about 35%, about 40%, about 45%, about 50%, about 55%, about 60%, about 65%, about 70%, about 75%, or about 80% by weight of the cement slurries.

The water may be from any source provided that it does not contain an excess of compounds that may undesirably affect other components in the cement slurries. For example, a cement slurry may include fresh water or saltwater. Saltwater generally may include one or more dissolved salts therein and may be saturated or unsaturated as desired for a particular application. Seawater or brines may be suitable for use in some examples. Further, the water may be present in an amount sufficient to form a pumpable slurry. In certain examples, the water may be present in the cement slurry in an amount in the range of from about 33% to about 200% by weight of the cementitious materials. For example, the water cement may be present in an amount ranging between any of and/or including any of about 33%, about 50%, about 75%, about 100%, about 125%, about 150%, about 175%, or about 200% by weight of the cementitious materials. The cementitious materials referenced may include all components which contribute to the compressive strength of the cement slurry such as the hydraulic cement and supplementary cementitious materials, for example.

As mentioned above, the cement slurry may include supplementary cementitious materials. The supplementary cementitious material may be any material that contributes to the desired properties of the cement slurry. Some supplementary cementitious materials may include, without limitation, fly ash, blast furnace slag, silica fume, pozzolans, kiln dust, and clays, for example.

The cement slurry may include kiln dust as a supplementary cementitious material. “Kiln dust,” as that term is used herein, refers to a solid material generated as a by-product of the heating of certain materials in kilns. The term “kiln dust” as used herein is intended to include kiln dust made as described herein and equivalent forms of kiln dust. Depending on its source, kiln dust may exhibit cementitious properties in that it can set and harden in the presence of water. Examples of suitable kiln dusts include cement kiln dust, lime kiln dust, and combinations thereof. Cement kiln dust may be generated as a by-product of cement production that is removed from the gas stream and collected, for example, in a dust collector. Usually, large quantities of cement kiln dust are collected in the production of cement that are commonly disposed of as waste. The chemical analysis of the cement kiln dust from various cement manufactures varies depending on a number of factors, including the particular kiln feed, the efficiencies of the cement production operation, and the associated dust collection systems. Cement kiln dust generally may include a variety of oxides, such as SiO₂, Al₂O₃, Fe₂O₃, CaO, MgO, SO₃, Na₂O, and K₂O. The chemical analysis of lime kiln dust from various lime manufacturers varies depending on several factors, including the particular limestone or dolomitic limestone feed, the type of kiln, the mode of operation of the kiln, the efficiencies of the lime production operation, and the associated dust collection systems. Lime kiln dust generally may include varying amounts of free lime and free magnesium, lime stone, and/or dolomitic limestone and a variety of oxides, such as SiO₂, Al₂O₃, Fe₂O₃, CaO, MgO, SO₃, Na₂O, and K₂O, and other components, such as chlorides. A cement kiln dust may be added to the cement slurry prior to, concurrently with, or after activation. Cement kiln dust may include a partially calcined kiln feed which is removed from the gas stream and collected in a dust collector during the manufacture of cement. The chemical analysis of CKD from various cement manufactures varies depending on a number of factors, including the particular kiln feed, the efficiencies of the cement production operation, and the associated dust collection systems. CKD generally may comprise a variety of oxides, such as SiO₂, Al₂O₃, Fe₂O₃, CaO, MgO, SO₃, Na₂O, and K₂O. The CKD and/or lime kiln dust may be included in examples of the cement slurry in an amount suitable for a particular application.

In some examples, the cement slurry may further include one or more of slag, natural glass, shale, amorphous silica, or metakaolin as a supplementary cementitious material. Slag is generally a granulated, blast furnace by-product from the production of cast iron including the oxidized impurities found in iron ore. The cement may further include shale. A variety of shales may be suitable, including those including silicon, aluminum, calcium, and/or magnesium. Examples of suitable shales include vitrified shale and/or calcined shale. In some examples, the cement slurry may further include amorphous silica as a supplementary cementitious material. Amorphous silica is a powder that may be included in embodiments to increase cement compressive strength. Amorphous silica is generally a byproduct of a ferrosilicon production process, wherein the amorphous silica may be formed by oxidation and condensation of gaseous silicon suboxide, SiO, which is formed as an intermediate during the process

In some examples, the cement slurry may further include a variety of fly ashes as a supplementary cementitious material which may include fly ash classified as Class C, Class F, or Class N fly ash according to American Petroleum Institute, API Specification for Materials and Testing for Well Cements, API Specification 10, Fifth Ed., Jul. 1, 1990. In some examples, the cement slurry may further include zeolites as supplementary cementitious materials. Zeolites are generally porous alumino-silicate minerals that may be either natural or synthetic. Synthetic zeolites are based on the same type of structural cell as natural zeolites and may comprise aluminosilicate hydrates. As used herein, the term “zeolite” refers to all natural and synthetic forms of zeolite.

Where used, one or more of the aforementioned supplementary cementitious materials may be present in the cement slurry. For example, without limitation, one or more supplementary cementitious materials may be present in an amount of about 0.1% to about 80% by weight of the cement slurry. For example, the supplementary cementitious materials may be present in an amount ranging between any of and/or including any of about 0.1%, about 10%, about 20%, about 30%, about 40%, about 50%, about 60%, about 70%, or about 80% by weight of the cement.

In some examples, the cement slurry may further include hydrated lime. As used herein, the term “hydrated lime” will be understood to mean calcium hydroxide. In some embodiments, the hydrated lime may be provided as quicklime (calcium oxide) which hydrates when mixed with water to form the hydrated lime. The hydrated lime may be included in examples of the cement slurry, for example, to form a hydraulic composition with the supplementary cementitious components. For example, the hydrated lime may be included in a supplementary cementitious material-to-hydrated-lime weight ratio of about 10:1 to about 1:1 or 3:1 to about 5:1. Where present, the hydrated lime may be included in the set cement slurry in an amount in the range of from about 10% to about 100% by weight of the cement slurry, for example. In some examples, the hydrated lime may be present in an amount ranging between any of and/or including any of about 10%, about 20%, about 40%, about 60%, about 80%, or about 100% by weight of the cement slurry. In some examples, the cementitious components present in the cement slurry may consist essentially of one or more supplementary cementitious materials and the hydrated lime. For example, the cementitious components may primarily comprise the supplementary cementitious materials and the hydrated lime without any additional components (e.g., Portland cement, fly ash, slag cement) that hydraulically set in the presence of water.

Lime may be present in the cement slurry in several; forms, including as calcium oxide and or calcium hydroxide or as a reaction product such as when Portland cement reacts with water. Alternatively, lime may be included in the cement slurry by amount of silica in the cement slurry. A cement slurry may be designed to have a target lime to silica weight ratio. The target lime to silica ratio may be a molar ratio, molal ratio, or any other equivalent way of expressing a relative amount of silica to lime. Any suitable target time to silica weight ratio may be selected including from about 10/90 lime to silica by weight to about 40/60 lime to silica by weight. Alternatively, about 10/90 lime to silica by weight to about 20/80 lime to silica by weight, about 20/80 lime to silica by weight to about 30/70 lime to silica by weight, or about 30/70 lime to silica by weight to about 40/63 lime to silica by weight.

Other additives suitable for use in subterranean cementing operations also may be included in embodiments of the cement slurry. Examples of such additives include, but are not limited to: weighting agents, lightweight additives, gas-generating additives, mechanical-property-enhancing additives, lost-circulation materials, filtration-control additives, fluid-loss-control additives, defoaming agents, foaming agents, thixotropic additives, and combinations thereof. In embodiments, one or more of these additives may be added to the cement slurry after storing but prior to the placement of a cement slurry into a subterranean formation. In some examples, the cement slurry may further include a dispersant. Examples of suitable dispersants include, without limitation, sulfonated-formaldehyde-based dispersants (e.g., sulfonated acetone formaldehyde condensate) or polycarboxylated ether dispersants. In some examples, the dispersant may be included in the cement slurry in an amount in the range of from about 0.01% to about 5% by weight of the cementitious materials. In specific examples, the dispersant may be present in an amount ranging between any of and/or including any of about 0.01%, about 0.1%, about 0.5%, about 1%, about 2%, about 3%, about 4%, or about 5% by weight of the cementitious materials.

In some examples, the cement slurry may further include a set retarder. A broad variety of set retarders may be suitable for use in the cement slurries. For example, the set retarder may comprise phosphonic acids, such as ethylenediamine tetra(methylene phosphonic acid), diethylenetriamine penta(methylene phosphonic acid), etc.; lignosulfonates, such as sodium lignosulfonate, calcium lignosulfonate, etc.; salts such as stannous sulfate, lead acetate, monobasic calcium phosphate, organic acids, such as citric acid, tartaric acid, etc.; cellulose derivatives such as hydroxyl ethyl cellulose (HEC) and carboxymethyl hydroxyethyl cellulose (CMHEC); synthetic co- or ter-polymers comprising sulfonate and carboxylic acid groups such as sulfonate-functionalized acrylamide-acrylic acid co-polymers; borate compounds such as alkali borates, sodium metaborate, sodium tetraborate, potassium pentaborate; derivatives thereof, or mixtures thereof. Examples of suitable set retarders include, among others, phosphonic acid derivatives. Generally, the set retarder may be present in the cement slurry in an amount sufficient to delay the setting for a desired time. In some examples, the set retarder may be present in the cement slurry in an amount in the range of from about 0.01% to about 10% by weight of the cementitious materials. In specific examples, the set retarder may be present in an amount ranging between any of and/or including any of about 0.01%, about 0.1%, about 1%, about 2%, about 4%, about 6%, about 8%, or about 10% by weight of the cementitious materials.

In some examples, the cement slurry may further include an accelerator. A broad variety of accelerators may be suitable for use in the cement slurries. For example, the accelerator may include, but are not limited to, aluminum sulfate, alums, calcium chloride, calcium nitrate, calcium nitrite, calcium formate, calcium sulphoaluminate, calcium sulfate, gypsum-hemihydrate, sodium aluminate, sodium carbonate, sodium chloride, sodium silicate, sodium sulfate, ferric chloride, or a combination thereof. In some examples, the accelerators may be present in the cement slurry in an amount in the range of from about 0.01% to about 10% by weight of the cementitious materials. In specific examples, the accelerators may be present in an amount ranging between any of and/or including any of about 0.01%, about 0.1%, about 1%, about 2%, about 4%, about 6%, about 8%, or about 10% by weight of the cementitious materials.

Cement slurries generally should have a density suitable for a particular application. By way of example, the cement slurry may have a density in the range of from about 8 pounds per gallon (“ppg”) (959 kg/m³) to about 20 ppg (2397 kg/m³), or about 8 ppg to about 12 ppg (1437. kg/m³), or about 12 ppg to about 16 ppg (1917.22 kg/m³), or about 16 ppg to about 20 ppg, or any ranges therebetween. Examples of the cement slurry may be foamed or unfoamed or may comprise other means to reduce their densities, such as hollow microspheres, low-density elastic beads, or other density-reducing additives known in the art.

The cement slurries disclosed herein may be used in a variety of subterranean applications, including primary and remedial cementing. The cement slurries may be introduced into a subterranean formation and allowed to set. In primary cementing applications, for example, the cement slurries may be introduced into the annular space between a conduit located in a wellbore and the walls of the wellbore (and/or a larger conduit in the wellbore), wherein the wellbore penetrates the subterranean formation. The cement slurry may be allowed to set in the annular space to form an annular sheath of hardened cement. The cement slurry may form a barrier that prevents the migration of fluids in the wellbore. The cement slurry may also, for example, support the conduit in the wellbore. In remedial cementing applications, the cement slurry may be used, for example, in squeeze cementing operations or in the placement of cement plugs. By way of example, the cement slurry may be placed in a wellbore to plug an opening (e.g., a void or crack) in the formation, in a gravel pack, in the conduit, in the cement sheath, and/or between the cement sheath and the conduit (e.g., a micro annulus).$

Accordingly, the methods of the present disclosure analyze suitability of a cement compositions for use in wells that may experience cyclic loads. The methods may include any of the various features disclosed herein, including one or more of the following statements.
Statement 1. A method comprises selecting cement compositions; performing wellbore integrity analyses using models for cement sheaths, each cement sheath comprising a selected cement composition; and determining a number of cycles to failure for each cement sheath.
Statement 2. The method of the statement 1, further comprising producing at least one selected cement composition based on the number of cycles to failure.
Statement 3. The method of any of the preceding statements, further comprising receiving pressure, temperature, and time data for each cement sheath.
Statement 4. The method of any of the preceding statements, further comprising determining deviatoric stress levels from the wellbore integrity analyses.
Statement 5. The method of any of the preceding statements, further comprising receiving the deviatoric stress levels with a fatigue model.
Statement 6. The method of any of the preceding statements, further comprising generating the models of the cement sheaths.
Statement 7. The method of any of the preceding statements, further comprising determining an objective function for at least one selected cement composition.
Statement 8. The method of any of the preceding statements, wherein determining the objective function comprises determining at least one of a CO₂ footprint, cost of goods sold (COGS), or material usage.
Statement 9. The method of any of the preceding statements, further comprising determining a minimum value for the CO₂ footprint, cost of goods sold (COGS), or material usage.
Statement 10. The method of any of the preceding statements, further comprising determining a maximum value for the CO₂ footprint, cost of goods sold (COGS), or material usage.
Statement 11. A method comprising: selecting cement compositions; performing wellbore integrity analyses using models for cement sheaths, each cement sheath comprising a selected cement composition; determining a number of cycles to failure for each cement sheath; and determining an objective function for at least one selected cement composition.
Statement 12. The method of any of the statement 11, wherein determining the objective function comprises determining at least one of a CO₂ footprint, cost of goods sold (COGS), or material usage.
Statement 13. The method of any of the statements 11-12, further comprising determining a minimum value for the CO₂ footprint, cost of goods sold (COGS), or material usage.
Statement 14. The method of any of the statements 11-13, further comprising producing the at least one selected cement composition based on the minimum value.
Statement 15. The method of any of the statements 11-14, further comprising determining a maximum value for the CO₂ footprint, cost of goods sold (COGS), or material usage.
Statement 16. The method of any of the statements 11-15, further comprising producing the at least one selected cement composition based on the maximum value.
Statement 17. The method of any of the statements 11-16, further comprising generating the models.
Statement 18. The method of any of the statements 11-17, further comprising receiving pressure, temperature, and time data for each cement sheath.
Statement 19. The method of any of the statements 11-18, further comprising determining deviatoric stress levels from the wellbore integrity analysis for each cement sheath.
Statement 20. The method of any of the statements 11-19, further comprising receiving the deviatoric stress levels with a fatigue model.

It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the elements that it introduces.

For the sake of brevity, only certain ranges are explicitly disclosed herein. However, ranges from any lower limit may be combined with any upper limit to recite a range not explicitly recited as well as ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present embodiments are well adapted to attain the ends and advantages mentioned as well as those that are inherent therein. The particular embodiments disclosed above are illustrative only, as the present embodiments may be modified and practiced in different but equivalent manners. Although individual embodiments are discussed, all combinations of each embodiment are contemplated and covered by the disclosure. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative embodiments disclosed above may be altered or modified and all such variations are considered within the scope and spirit of the present disclosure. If there is any conflict in the usages of a word or term in this specification and one or more patent(s) or other documents that may be incorporated herein by reference, the definitions that are consistent with this specification should be adopted.

What is claimed is:

1. A method comprising:
selecting cement compositions;
performing wellbore integrity analyses using models for cement sheaths, each cement sheath comprising a selected cement composition; and
determining a number of cycles to failure for each cement sheath.

2. The method of claim 1, further comprising producing at least one selected cement composition based on the number of cycles to failure.

3. The method of claim 1, further comprising receiving pressure, temperature, and time data for each cement sheath.

4. The method of claim 1, further comprising determining deviatoric stress levels from the wellbore integrity analyses.

5. The method of claim 4, further comprising receiving the deviatoric stress levels with a fatigue model.

6. The method of claim 1, further comprising generating the models of the cement sheaths.

7. The method of claim 6, further comprising determining an objective function for at least one selected cement composition.

8. The method of claim 7, wherein determining the objective function comprises determining at least one of a CO₂ footprint, cost of goods sold (COGS), or material usage.

9. The method of claim 8, further comprising determining a minimum value for the CO₂ footprint, cost of goods sold (COGS), or material usage.

10. The method of claim 1, further comprising determining a maximum value for the CO₂ footprint, cost of goods sold (COGS), or material usage.

11. A method comprising:
selecting cement compositions;
performing wellbore integrity analyses using models for cement sheaths, each cement sheath comprising a selected cement composition;
determining a number of cycles to failure for each cement sheath; and
determining an objective function for at least one selected cement composition.

12. The method of claim 11, wherein determining the objective function comprises determining at least one of a CO₂ footprint, cost of goods sold (COGS), or material usage.

13. The method of claim 12, further comprising determining a minimum value for the CO₂ footprint, cost of goods sold (COGS), or material usage.

14. The method of claim 13, further comprising producing the at least one selected cement composition based on the minimum value.

15. The method of claim 15, further comprising determining a maximum value for the CO₂ footprint, cost of goods sold (COGS), or material usage.

16. The method of claim 11, further comprising producing the at least one selected cement composition based on the maximum value.

17. The method of claim 11, further comprising generating the models.

18. The method of claim 11, further comprising receiving pressure, temperature, and time data for each cement sheath.

19. The method of claim 11, further comprising determining deviatoric stress levels from the wellbore integrity analysis for each cement sheath.

20. The method of claim 19, further comprising receiving the deviatoric stress levels with a fatigue model.
